(19) United States
(12) Patent Application Publication
(10) Pub. No.: US 2016/0297681 A1
(43) Pub. Date: Oct. 13, 2016

(54) LARGE-AREA CARBON NANOMESH FROM POLYMER AND METHOD OF PREPARING THE SAME

(71) Applicant: Korea Institute of Science and Technology, Seoul (KR)

(72) Inventors: Han-Ik JOH, Wanju-gun (KR); Su Young SON, Wanju-gun (KR); Sung Ho LEE, Wanju-gun (KR); Tae-Wook KIM, Wanju-gun (KR)

(73) Assignee: Korea Institute of Science and Technology, Seoul (KR)

(21) Appl. No.: 15/183,282

(22) Filed: Jun. 15, 2016

Related U.S. Application Data
(63) Continuation-in-part of application No. 13/871,285, filed on Apr. 26, 2013, now Pat. No. 9,409,781.

(30) Foreign Application Priority Data
Feb. 12, 2013 (KR) 10-2013-0014836

(51) Int. Cl. C01B 31/04; C23C 14/06; C08J 9/26; C23C 16/26; H01B 1/04; C09D 5/24

(52) U.S. Cl. CPC C01B 31/0446; H01B 1/04; C09D 5/24; C08J 9/26; C23C 16/26; C23C 14/0605; B82Y 40/00

(57) ABSTRACT

The present disclosure relates to a polymer-based large-area carbon nanomesh and a method for preparing the same. More particularly, the present disclosure provides a method for preparing a carbon nanomesh such as graphene nanomesh, including: preparing a polymer nanofilm by coating a solution of a block copolymer or a polymer mixture thereof on a substrate; stabilizing the polymer nanofilm by annealing such that the polymer nanofilm is phase-separated, a hole-forming polymer is removed and, at the same time, a nanomesh-forming polymer is cyclized and forms a stabilized polymer nanomesh; and carbonizing the stabilized polymer nanomesh by annealing at high temperature to prepare a carbon nanomesh. Using the phase separation and cyclization, a large-area carbon nanomesh with superior activity can be prepared simply with high reproducibility in large scale.

### RELATED APPLICATIONS

This application is a continuation-in-part of co-pending patent application Ser. No. 13/871,285, which application was filed on Apr. 26, 2013 and claims priority to Korean Patent Application No. 10-2013-0014836, filed on Feb. 12, 2013.

### BACKGROUND

1. Field

The present disclosure relates to a polymer-based large-area carbon nanomesh and a method for preparing the same. More particularly, it relates to a polymer-based large-area polymer carbon nanomesh prepared using phase separation and cyclization characteristics of hole-forming polymer and nanomesh-forming polymer via a simple process with high reproducibility, thus being producible in large scale, and a method for preparing the same.

2. Description of the Related Art

Graphene is a substance composed of carbon, with atoms arranged in a hexagonal pattern with a planar (2-dimensional) structure, exhibiting properties different from those of graphite or carbon nanotube having a 1-dimensional structure or fullerene having a 0-dimensional structure. It is reported that a single-layer graphene film has unique characteristics distinguished from those of other carbon materials, with a surface area of about 2600 m²/g and an electron mobility of 15,000-200,000 cm²/Vs. In particular, electrons move on the graphene film with a speed close to that of light, because they flow on the graphene film as if they were massless.

The graphene film is mainly prepared by the Scotch tape method, epitaxial growth on silicon carbide, chemical method using a reducing agent or chemical vapor deposition.

The Scotch tape method physically exfoliates a graphene film from graphite using an adhesive tape. Although graphene with a good crystal structure can be obtained easily, the graphene in this way is about tens of micrometers in size and thus is limited in application to electronic devices or electrodes.

The epitaxial method separates carbon from the inside of silicon carbide crystals to the surface at high temperature to form a honeycomb structure peculiar to graphene. This method allows production of graphene films with uniform crystallinity, but electrical properties are relatively inferior to those obtained by other methods. Further, the silicon carbide wafer is very expensive.

The chemical method using a reducing agent involves oxidization of graphite, pulverization of the oxidized graphite to form oxidized graphene and reduction of the oxidized graphene using a reducing agent such as hydrazine. Although this method is advantageous in that the process is simple and carried out at low temperature, the oxidized graphene may not be completely reduced chemically, leading to defects on graphene and consequently poor electrical properties.

Lastly, the chemical vapor deposition deposits a carbon-containing gas at high temperature on a metallic catalyst film on which graphene can grow to obtain graphene films. Although this method allows high-quality large-area graphene films, the procedure of recovering the metallic catalyst film is complicated and difficult.

Graphenes prepared in those ways are applicable to various fields, from semiconductor devices to flexible electronic devices. However, since graphene is a semi-metal with a zero band gap, its application for a gate for current control in a field-effect transistor (FET) is limited.

In general, there are two methods for controlling the band gap of graphene.

The first method is to cut a single-walled carbon nanotube to obtain a graphene nanoribbon with a width not greater than 10 nm. Although this method provides semiconductor properties by opening of the band gap of graphene, it is inapplicable to commercialization of graphene.

The second method is to prepare a graphene nanomesh using a shadow mask. The method for preparing a graphene or carbon nanomesh involves the following six steps. 1) Graphene is physically exfoliated from graphite and transferred onto a substrate. 2) Under an etching condition, silicon oxide is deposited on the graphene to a thickness of tens of nanometers for selective removal of the graphene and coating of a shadow mask. 3) A block copolymer serving as a shadow mask is coated on the silicon oxide layer and a porous polymer film is prepared through annealing of the block copolymer. 4) The silicon oxide layer is selectively removed by injecting reactive ions to result in a pattern similar to that of the polymer film. 5) A graphene nanomesh having a pattern similar to that of the resulting silicon oxide layer is prepared by removing exposed graphene using oxygen plasma. In this step, the porous polymer nanofilm is removed by the oxygen plasma treatment. 6) The prepared sample is immersed in hydrofluoric acid to remove the porous silicon oxide layer. Thus prepared graphene nanomesh has a controlled geometry with an inter-hole distance of not greater than 10 nm, thus exhibiting a controlled band gap and semiconductor properties. However, this method realizes the graphene nanomesh on a small piece of graphene and requires a complicated process involving the six steps, as described above. In addition, the reactive ion and oxygen plasma processes are expensive since they require high-vacuum conditions.

### SUMMARY

The present disclosure is directed to providing a polymer nanomesh and a carbon nanomesh prepared using a phase separation and cyclization characteristics of a block copolymer of hole-forming polymer and nanomesh-forming polymer or a polymer mixture of hole-forming polymer and nanomesh-forming polymer. Specifically, polymer phase separation and thermal stabilization of the block copolymer or the polymer mixture are induced to provide a polymer nanomesh with two dimensional holes without the silicon oxide deposition or high-vacuum etching and a carbon nanomesh with two dimensional holes having a geometry of controlled band gap is obtained through a carbonization of the polymer nanomesh.

In one aspect, there is provided a polymer nanomesh consisting essentially of a planar structure, wherein the planar structure of the polymer nanomesh comprises a cyclized nanomesh-forming polymer and two-dimensional holes arranged on the planer structure.

Herein, a nanomesh-forming polymer is cyclized to form the polymer nanomesh, and two-dimensional holes are formed by removal of hole-forming polymer.

Since the hole-forming polymer and the nanomesh-forming polymer are phase-separated with each other, morphology of the polymer nanomesh may depend on morphology of the phase-separation of the hole-forming polymer and the nanomesh-forming polymer. Accordingly, the two-dimensional holes are not formed on a phase of nanomesh-forming polymer but are formed on a phase of hole-forming polymer, i.e., the hole-forming polymer is removed, thereby forming the two-dimensional hole.

In other aspect, there is provided a carbon nanomesh consisting essentially of a planar structure, wherein the planar structure of the carbon nanomesh comprises a cyclic structure of carbon atoms and two dimensional holes arranged on the planer structure, wherein the cyclic structure of carbon atoms comes from a carbonization of a cyclized nanomesh-forming polymer.

In an example embodiment, the carbon nanomesh may be a carbonization product of the said polymer nanomesh. Thus, as like the polymer nanomesh, morphology of the carbon nanomesh may depend on morphology of the phase-separation of the hole-forming polymer and the nanomesh-forming polymer.

In an example embodiment, the carbon nanomesh may have two dimensional holes with a hole size of 1 nm˜1 μm.

In an example embodiment, the two dimensional holes has a shape of thin disc.

In an example embodiment, in the carbon nanomesh, as the size of the holes increase, inter-hole distance decreases.

In an example embodiment, the carbon nanomesh may have a length of 1 nm to 1 m in horizontal and vertical directions, respectively.

In an example embodiment, the carbon nanomesh may have a thickness of 0.4 nm or more.

In an example embodiment, the carbon nanomesh has a geometry of inter-hole distance of 1 nm to 1 μm.

In an example embodiment, the carbon nanomesh has a band gap of 1 meV˜1 eV.

In an example embodiment, a band gap of the carbon nanomesh is controlled by geometry of the inter-hole of the carbon nanomesh.

In an example embodiment, the carbon nanomesh may be a graphene nanomesh.

In another aspect, there is provided a carbon laminate containing the carbon nanomesh. Herein, the carbon laminate may comprise multi-layered carbon nanomesh such as 1˜300 layers or specifically 1˜90 layers of carbon nanomesh. Further, the carbon laminate may have a thickness of 100 nm or less or specifically 30 nm or less.

In another aspect, there is provided a method for controlling a band gap of carbon nanomesh, comprising preparing a polymer nanofilm by coating a solution of a block copolymer of a hole-forming polymer and a nanomesh-forming polymer or by coating a solution of a polymer mixture of a hole-forming polymer and a nanomesh-forming polymer, on a substrate, stabilizing the polymer nanofilm such that the hole-forming polymer is removed and the nanomesh-forming polymer is cyclized and forms a stabilized polymer nanomesh with two dimensional holes; and carbonizing the stabilized polymer nanomesh with two dimensional holes to prepare a carbon nanomesh with two dimensional holes, wherein the band gap of the carbon nanomesh is controlled by a geometry of the inter-hole distance of the carbon nanomesh.

In accordance with the present disclosure, hole size, inter-hole distance, thickness, etc. of the polymer nanomesh and carbon nanomesh can be easily controlled. Further, band gap of the carbon nanomesh can be easily controlled to suit for various applications. Furthermore, a large-area carbon nanomesh with superior activity may be produced in large scale.

### BRIEF DESCRIPTION OF THE DRAWINGS

The above and other aspects, features and advantages of the disclosed exemplary embodiments will be more apparent from the following detailed description taken in conjunction with the accompanying drawings in which:

FIG. 1 shows a preparation process of Example 1 according to an exemplary embodiment of the present disclosure and images obtained at different steps;

FIG. 2 shows atomic force microscopic (AFM) images of graphene nanomeshes prepared in Example 1 according to an exemplary embodiment of the present disclosure with varying mixing ratios of a polymer mixture;

FIG. 3 shows a distribution of the inter-hole distance of graphene nanomeshes prepared in Example 1 according to an exemplary embodiment of the present disclosure with varying mixing ratios of a polymer mixture;

FIG. 4 shows Raman spectra of graphene nanomeshes prepared in Example 1 according to an exemplary embodiment of the present disclosure with varying mixing ratios of a polymer mixture;

FIG. 5 shows an image of a graphene nanomesh prepared in Example 1 according to an exemplary embodiment of the present disclosure with a polymer mixture mixing ratio of 4:6;

FIG. 6 shows a preparation process of Example 2 according to an exemplary embodiment of the present disclosure and images obtained at different steps;

FIG. 7 shows surface images of graphene nanomeshes prepared in Example 2 according to an exemplary embodiment of the present disclosure;

FIG. 8 shows a preparation process of Example 3 according to an exemplary embodiment of the present disclosure and images obtained at different steps; and

FIG. 9 shows surface images of graphene nanomeshes prepared in Example 3 according to an exemplary embodiment of the present disclosure with additional annealing.

FIG. 10 shows Raman spectra of graphene nanomeshes prepared in Example 1 and Example 2 according to an exemplary embodiment of the present disclosure.

### DETAILED DESCRIPTION

Hereinafter, the present disclosure is described in detail.

As used herein, the term “hole-forming polymer” refers to a polymer which is removed during stabilization to form two dimensional holes and the term “nanomesh-forming polymer” refers to a polymer which forms a polymer nanomesh during stabilization.

As used herein, the term “two dimensional holes” means through-holes arranged on one same plane or one same planar structure. The holes may be arranged to have a pattern and/or uniform size on one same plane or one same planer structure. The holes may have a shape of thin disc with a size of 1 nm˜1 um. The thickness of the holes is a thickness of the plane or planar structure.

As used herein, the term “planar structure” or “plane” refers to a thin sheet-like structure with nanosized thickness. The thickness of the planar structure or plane is different from the vertical size and horizontal size of the planer structure or the plane by at least one order of magnitude (i.e. at least 10 times).

As used herein, when it is said that a nanomesh-forming polymer is dissociation free in forming the polymer nanomesh or when it is said that a nanomesh-forming polymer is cyclized without dissociation to form the polymer nanomesh, this means that the polymer nanomesh is made of cyclized structure of the nanomesh-forming polymer and the nanomesh-forming polymer does not experience its dissociation when forming the polymer nanomesh.

As used herein, the term “carbon nanomesh” includes a graphene nanomesh. That is, carbon nanomesh is a generic term of graphene nanomesh. One example of the carbon nanomesh may be a graphene nanomesh. Carbon nanomesh may further include carbons other than graphene, Thus, it should be understood that graphene nanomesh also infringes claims related to carbon nanomesh.

In accordance with the present disclosure, a large-area carbon nanomesh can be prepared through a three-step process including polymer nanofilm preparation, stabilization and carbonization. When compared with the existing art, the processes of silicon compound deposition or high-vacuum etching can be omitted and, thus, production cost can be saved. Accordingly, a large-area carbon nanomesh with superior activity can be produced in large scale.

In example embodiments of the present disclosure, a method for preparing a carbon nanomesh according to the present disclosure includes: preparing a polymer nanofilm by coating a solution of a block copolymer of hole-forming polymer and nanomesh-forming polymer or a polymer mixture of hole-forming polymer and nanomesh-forming polymer on a substrate; stabilizing the polymer nanofilm by annealing such that the polymer nanofilm is phase-separated, a hole-forming polymer is removed and, at the same time, a nanomesh-forming polymer forms a stabilized (cyclized) polymer nanomesh; and carbonizing the stabilized polymer nanomesh by annealing at high temperature to prepare a carbon nanomesh.

In another example embodiment of the present disclosure, a metal nanofilm may be deposited on the polymer nanofilm before or after the stabilization.

In another example embodiment of the present disclosure, during the carbonization, the carbon nanomesh may be graphitized at 1800-3000° C. under an atmosphere of inert gas, hydrogen gas, vacuum or a combination thereof.

First, in the preparation of the polymer nanofilm, a polymer nanofilm is prepared by coating a solution of a block copolymer of hole-forming polymer and nanomesh-forming polymer or a polymer mixture of hole-forming polymer and nanomesh-forming polymer on a substrate.

The block copolymer or the polymer mixture may be a block copolymer or polymer mixture of one or more polymer or monomer selected from a group consisting of polyacrylonitrile, polyolefin, polyvinyl, cellulose, lignin, natural polymer and pitch or a mixture thereof.

In non-limiting example embodiments, the hole-forming polymer may be PMMA, PS (polystyrene), PVA (polyvinyl alcohol), PEMA (polyethly methacrylate) and etc.

In non-limiting example embodiments, the nanomesh-forming polymer may be PAN, pitch, rayon, PIM (polymer of intrinsic microporosity), PAA (polyamic acid), PE (polyethylene) and etc.

Before, after or during the stabilization, the block copolymer of hole-forming polymer and nanomesh-forming polymer or the polymer mixture of hole-forming polymer and nanomesh-forming polymer is thermally annealed or solvent annealed in a temperature range that can affect one kind of polymer, thereby increasing mobility of the kind of polymer and inducing aggregation of like kind of polymers, i.e., aggregation of like kind of hole-forming polymers and aggregation of like kind of nanomesh-forming polymers (hereinafter, phase separation of polymer).

In particular, a hole size and an inter-hole distance of the carbon nanomesh may be controlled by controlling a mixing ratio of the polymer mixture of hole-forming polymer and nanomesh-forming polymer or by controlling a ratio of hole-forming polymer and nanomesh-forming polymer in block copolymer. Specifically, for example, the polymer mixture may contain the hole-forming polymer and the nanomesh-forming polymer with a mixing ratio (hole-forming polymer/nanomesh-forming polymer) of 0.01-100, more specifically 0.1-10.

The polymer that forms holes (i.e., the hole-forming polymer) should be decomposed at a relatively lower temperature or be more easily removed by a solvent as compared to the polymer that forms the nanomesh (i.e., the nanomesh-forming polymer). Accordingly, the hole-forming polymer needs to be relatively more easily removable. In an exemplary embodiment, the block copolymer or the polymer mixture may contain PMMA as the hole-forming polymer and PAN as the nanomesh-forming polymer.

The hole-forming polymer and the nanomesh-forming polymer may have a molecular weight of 100-10,000,000, more specifically, 10,000-1,000,000, respectively. It is because the phase separation pattern (e.g., lamella, gyroid, hexagonally packed cylinder, body-centered cubic, etc.) of the block copolymer or the polymer mixture becomes different in general depending on the kind of polymers, temperature, molecular weight, film thickness, or the like and there are hundreds or more combinations of polymers that can induce the phase separation of the polymer mixture.

In non-limiting example embodiments, the substrate on which the polymer is coated may be one or more of a silicon substrate, a silicon compound substrate such as silicon oxide, quartz, silicon nitride, silicon carbide, etc., a metal oxide substrate such as Al₂O₃, ZnO, etc., a group 3-5 compound semiconductor substrate such as GaN, GaAs, etc., although not being particularly limited thereto. For example, the substrate may include one or more transition metal selected from a group consisting of platinum (Pt), ruthenium (Ru), copper (Cu), iron (Fe), nickel (Ni), cobalt (Co), lead (Pd), tungsten (W), iridium (Ir), rhodium (Rh), strontium (Sr), cesium (Ce), praseodymium (Pr), neodymium (Nd), samarium (Sm) and rhenium (Re) or an alloy thereof or may include one or more non-transition metal selected from a group consisting of magnesium (Mg), boron (B) and aluminum (Al) or an alloy thereof.

The polymer solution is coated on the substrate. A coating method is not particularly limited but, specifically, may be one or more selected from a group consisting of spin coating, dip coating, bar coating, self-assembly, spraying, inkjet printing, gravure printing, gravure offset printing, flexography and screen printing.

A thickness of the polymer nanofilm prepared by coating the polymer solution is not particularly limited but may be in the order of tens of nanometers.

Next, in the stabilization, the prepared polymer nanofilm is heated such that the polymer nanofilm undergoes a phase-separation, the hole-forming polymer that is decomposed at low temperature is removed and, at the same time, the nanomesh-forming polymer forms a stabilized (cyclized) polymer nanomesh.

In an example embodiment, in the stabilization, the prepared polymer nanofilm may be formed into the polymer nanomesh by heating the polymer nanofilm at 400° C. or lower under an atmosphere of air, oxygen or vacuum. As a result of the heating, the polymer nanofilm undergoes a phase-separation, the hole-forming polymer is removed and, at the same time, the nanomesh-forming polymer is cyclized and forms the cyclic structure. Thus, a planar structure of the polymer nanomesh comprises a cyclized nanomesh-forming polymer and two-dimensional holes, which is formed by removal of hole-forming polymer.

In particular, for example, a polymer having a functional group with carbon and nitrogen atoms triply bonded (e.g., PAN, PIM, etc.) is cyclized at 400° C. or lower to result in a hexagonal structure. As a result, a polymer nanomesh comprising a cyclized nanomesh-forming polymer and two-dimensional holes may be obtained. Herein the nanomesh-forming polymer may be a building block (or building unit) of the polymer nanomesh such that the nanomesh-forming polymer is cyclized to form or build the polymer nanomesh, and two-dimensional holes are formed by removal of the hole-forming polymer. As long as the metal nanofilm which may serve as a catalyst is not used, the nanomesh-forming polymer is not dissociated.

In addition to the heating, the polymer nanofilm may also be formed into the polymer nanomesh by using a strongly alkaline aqueous solution, a strongly alkaline organic solution or a solvent with which only the pore-forming polymer reacts.

Also, the polymer nanofilm may be formed into the polymer nanomesh by applying plasma, ion beam, radioactive ray, ultraviolet light or microwave. In an example embodiment of the present disclosure, when the polymer nanofilm is treated with plasma in the presence of oxygen ions, phase separation and stabilization are achieved similarly to the heating. In particular, they occur at relatively lower temperature in the presence of oxygen and at around 400° C. under an inert gas atmosphere.

In addition, in order to perform stabilizing of the nanomesh-forming polymer with low heat generation and/or to start stabilizing of the nanomesh-forming polymer at low temperature, a nanomesh-forming polymer where polymer chain structure is modified, or a nanomesh-forming polymer where comonomer was used when polymerizing the nanomesh-forming polymer may be used as for the nanomesh-forming polymer.

For example, when polymerizing polyacrylonitrile (PAN) which is the nanomesh-forming polymer, comonomer such as itaconic acid (IA) or methacrylic acid (MA) may be added to acrylonitrile (AN) monomer, and as such PAN copolymer including acidic group may be obtained. Stabilizing of this PAN copolymer requires less heat generation as well as enables stabilization starting at lower temperature as compared to stabilizing of PAN homopolymer.

In an example embodiment, a metal nanofilm may be deposited on the polymer nanofilm before or after the stabilization to induce the formation of the nanomesh as well as to improve the properties of the finally prepared carbon nanomesh.

The metal nanofilm formed on the polymer nanofilm surface may improve crystallinity and structure of the carbon nanomesh, particularly graphene nanomesh, and, at the same time, reduce the inter-hole distance.

That is, in order to improve crystallinity of carbon nanomesh, a metal layer such as Ni layer to serve as a catalyst may be deposited on the polymer nanomesh. Explaining further in detail, during high-temperature carbonization of polymer nanomesh on which a metal layer is deposited, a polymer of the polymer nanomesh may be dissociated in the presence of the metal layer, and carbon atoms produced from dissociated polymer may be solved into the metal layer and form a solid solution. And then, when the temperature goes down after the carbonization, carbon atoms solved in the metal may come out of the metal again, i.e. be precipitated and rearranged in hexagonal cyclic form. Thereby, carbon nanomesh with improved crystallinity may be obtained. In such carbon nanomesh, defects in the crystal such as vacancy or amorphous carbon may be decreased and thereby the crystallinity may be improved.

In an example embodiment, the inter-hole distance of the carbon nanomesh made using metal nanofilm may be reduced 5-90%, for example 5˜50% or 5˜30% as compared to that of the carbon nanomesh made without using metal nanofilm.

A metal of the deposited metal nanofilm may include one or more transition metal selected from a group consisting of platinum (Pt), ruthenium (Ru), copper (Cu), iron (Fe), nickel (Ni), cobalt (Co), lead (Pd), tungsten (W), iridium (Ir), rhodium (Rh), strontium (Sr), cesium (Ce), praseodymium (Pr), neodymium (Nd), samarium (Sm) and rhenium (Re) or an alloy thereof or may include one or more non-transition metal selected from a group consisting of magnesium (Mg), boron (B) and aluminum (Al) or an alloy thereof.

The metal nanofilm may be deposited on the polymer nanofilm by thermal deposition, physical vapor deposition or chemical vapor deposition.

Also, the metal nanofilm may be formed by coating a metal precursor and then annealing without additional treatment. The metal precursor may be one or more selected from a group consisting of a metal chloride including CuCl₂, CoCl₂, OsCl₃, CrCl₃, (NH₃)₆RuCl₃, FeCl₃, NiCl₂, PdCl₂, RuCI₃ and H₂PtCl₆, a metal nitride including Pd(NO₃)₂, (NH₃)₄Pt(NO₃)₂, Fe(NO₃)₃ and Ni(NO₃)₂, iron acetlyacetonate, ferrocene and Pt(acac)₂.

The coating of the metal precursor may be performed by one or more coating method selected from a group consisting of spin coating, dip coating, bar coating, self-assembly, spraying, inkjet printing, gravure printing, gravure offset printing, flexography and screen printing.

Then, the stabilized polymer nanomesh is carbonized by annealing at high temperature to prepare the carbon nanomesh.

In an example embodiment, in the carbonization, the polymer nanomesh may be carbonized at 400-1800° C. under an atmosphere of inert gas, hydrogen gas, vacuum or a combination thereof. The carbonization may be performed while injecting a doping gas such as ammonia so as to dope dopant atoms into the carbon nanomesh surface to suit the application of the carbon nanomesh.

The doping gas may contain a group 3-7 element. Also, in order to obtain a high-quality carbon nanomesh, volatile carbon molecules may be injected together. The volatile carbon molecules may be acetylene, ethylene or methane.

During the carbonization, the carbon nanomesh may be graphitized at 1800-3000° C. under an atmosphere of inert gas, hydrogen gas, vacuum or a combination thereof in order to prepare a high-quality carbon nanomesh.

The graphitization is performed to allow the carbon atoms to form perfectly hexagonal rings. At the carbonization temperature (1800° C. or lower), a small quantity of heteroatoms may be included in the carbon nanomesh, resulting in decreased structural perfection of the carbon structure. If the annealing temperature is increased further, a structurally more perfect carbon material (in particular, graphene) can be prepared.

The prepared carbon nanomesh is a carbonization material of the said polymer nanomesh, and has a planar structure with two dimensional holes. This planar structure of the carbon nanomesh comprises two dimensional holes and a cyclic structure of carbon atoms or hexagonal ring structure of carbon atoms, which comes from the carbonization of the cyclized structure of nanomesh-forming polymer. Thus, it can be said that the cyclic structure of carbon atoms is a carbonized structure of a cyclized structure of nanomesh-forming polymer.

In an example embodiment, the carbon nanomesh may have two dimensional holes with a hole size of 1 nm˜1 μm.

In an example embodiment, in the carbon nanomesh, as the size of the holes increase, inter-hole distance decreases.

In an example embodiment, the carbon nanomesh may have a length of 1 nm to 1 m in horizontal and vertical directions, respectively.

In an example embodiment, the carbon nanomesh may have a thickness of 0.4 nm or more.

In an example embodiment, the carbon nanomesh has a geometry of inter-hole distance of 1 nm to 1 μm.

In an example embodiment, a band gap of the carbon nanomesh is controlled by geometry of the inter-hole of the carbon nanomesh. That is, the inter-hole distance can determine band gap of the carbon nanomesh.

In an example embodiment, the carbon nanomesh has a band gap of 1 meV˜1 eV.

In an example embodiment, the carbon nanomesh may be a graphene nanomesh.

In an example embodiment, the carbon nanomesh further comprises metal film.

A carbon laminate containing the prepared carbon nanomesh such as graphene nanomesh may be used for electronic devices such as transparent electrode, organic light-emitting diode (OLED), organic photovoltaic cell (OPVC), etc.

In an example embodiment, the carbon laminate may comprise multi-layered carbon nanomesh such as 1˜300 layers or specifically 1˜90 layers of carbon nanomesh. Further, the carbon laminate may have a thickness of 100 nm or less or specifically 30 nm or less.

According to the example embodiments of the present disclosure, band gap of the carbon nanomesh may be easily controlled, for example, by controlling a mixing ratio of polymer mixture or ratio of block copolymer. Further, the band gap of the carbon nanomesh may be controlled by selecting kinds of the nanomesh-forming polymer and hole-forming polymer, and/or by controlling the concentration of the polymer mixture or block copolymer, and/or by controlling of the molecular weight of the polymer mixture or block copolymer.

Provided further is a method for controlling a band gap of carbon nanomesh, the method may comprise preparing a polymer nanofilm by coating a solution of a block copolymer of a hole-forming polymer and a nanomesh-forming polymer or by coating a solution of a polymer mixture of a hole-forming polymer and a nanomesh-forming polymer, on a substrate, stabilizing the polymer nanofilm such that the hole-forming polymer is removed and the nanomesh-forming polymer is cyclized and forms a stabilized polymer nanomesh with two dimensional holes; and carbonizing the stabilized polymer nanomesh with two dimensional holes to prepare a carbon nanomesh with two dimensional holes, wherein the band gap of the carbon nanomesh is controlled by a geometry of the inter-hole distance of the carbon nanomesh.

### EXAMPLES

Hereinafter, a graphene nanomesh prepared using phase separation and cyclization of a block copolymer of hole-forming polymer and nanomesh-forming polymer or a polymer mixture of hole-forming polymer and nanomesh-forming polymer according to the present disclosure will be described in detail through examples. However, the following examples are for illustrative purposes only and it will be apparent to those of ordinary skill in the art that the scope of the present disclosure is not limited by the examples.

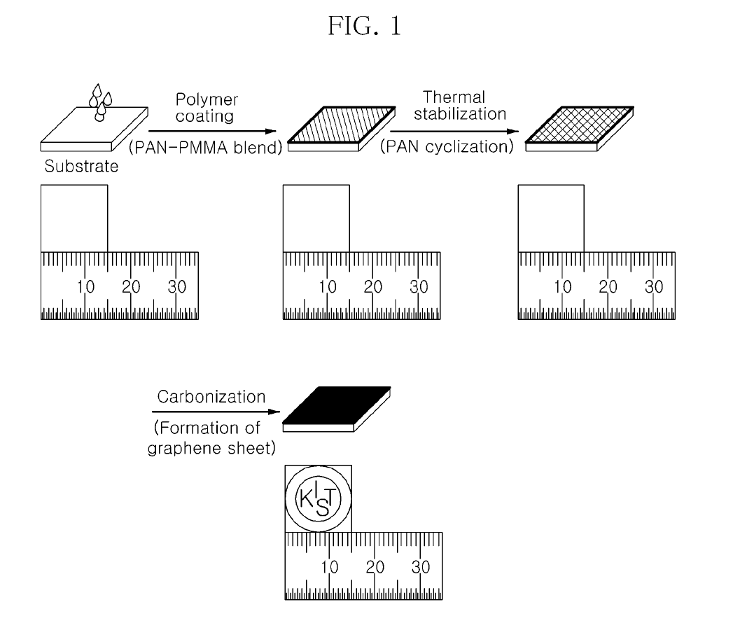

As shown in FIG. 1, graphene nanomeshes according to the present disclosure are prepared by first dissolving polyacrylonitrile (PAN) and poly(methyl methacrylate) (PMMA) are dissolved in a polar organic solvent dimethylformamide (DMF) for about 1 hour using a stirrer. The resulting mixture is coated on a quartz substrate using a spin coater. To induce the coated polymer to be formed into a nanomesh, annealing is performed at 270° C. for 2 hours under an air atmosphere. The nanomesh is carbonized in a carbonization furnace under a controlled gas atmosphere.

### Example 1

In order to investigate the effect of the mixing ratio of the polymer mixture on the properties of the prepared graphene nanomeshes, a polymer solution containing a nanomesh-forming polymer and a hole-forming polymer with a mixing ratio of 6:4, 5:5 or 4:6 was prepared.

The polymer solution was coated on a 1.5 cm×1.5 cm quartz substrate using a spin coater.

The coated polymer nanofilm was subject to a stabilization under an air atmosphere at 270° C. for 2 hrs. During the stabilization, nanomesh-forming polymer was cyclized and hole-forming polymer was removed to produce a polymer nanomesh having a planar structure where two-dimensional holes are formed by the removal of the hole-forming polymer. Then, the polymer nanomesh was carbonized under an argon/hydrogen gas mixture atmosphere by heating to 1200° C. at a rate of 5° C./min to prepare graphene nanomeshes.

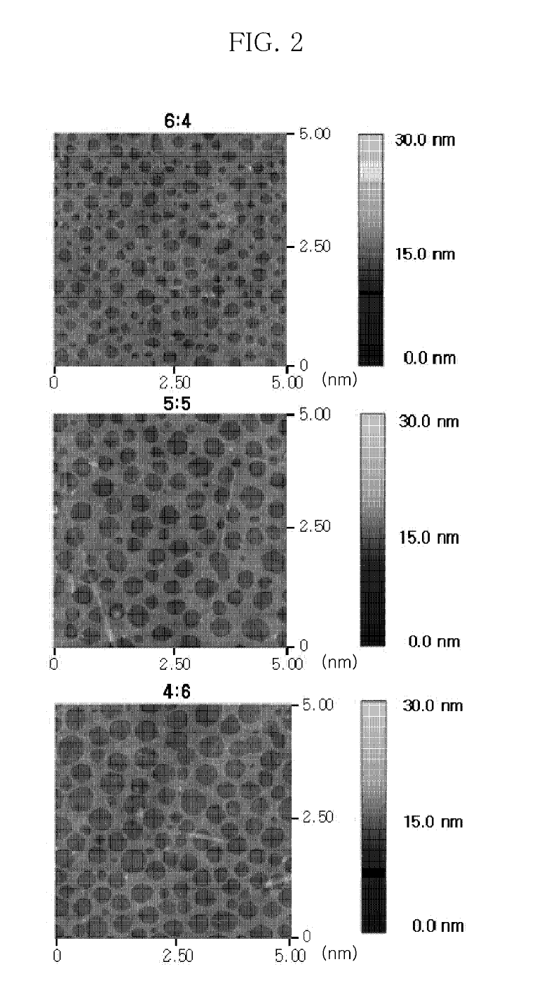

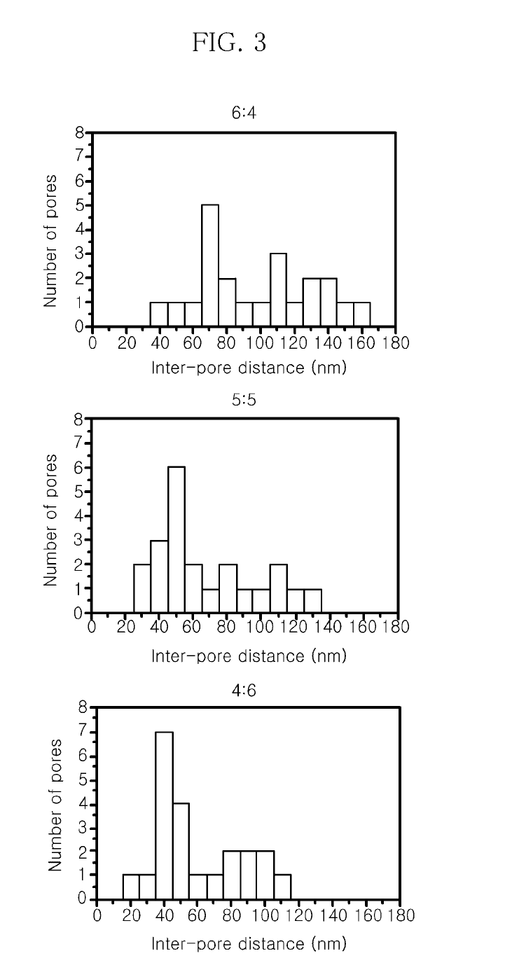

The surface of thus prepared graphene nanomeshes was observed under an atomic force microscope (AFM) and the result is shown in FIG. 2. Based on the result, inter-hole distance and average number of holes were determined (FIG. 3).

As the proportion of the hole-forming polymer was higher, the hole size was larger and the inter-hole distance was smaller in the prepared graphene nanomeshes. Accordingly, it was confirmed that the hole size and inter-hole distance of the graphene nanomeshes are greatly dependent on the mixing ratio of the polymer mixture.

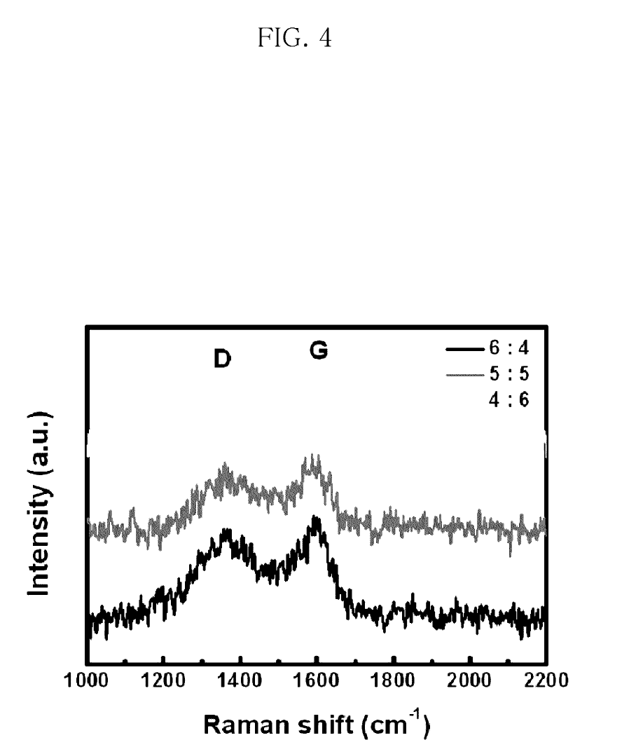

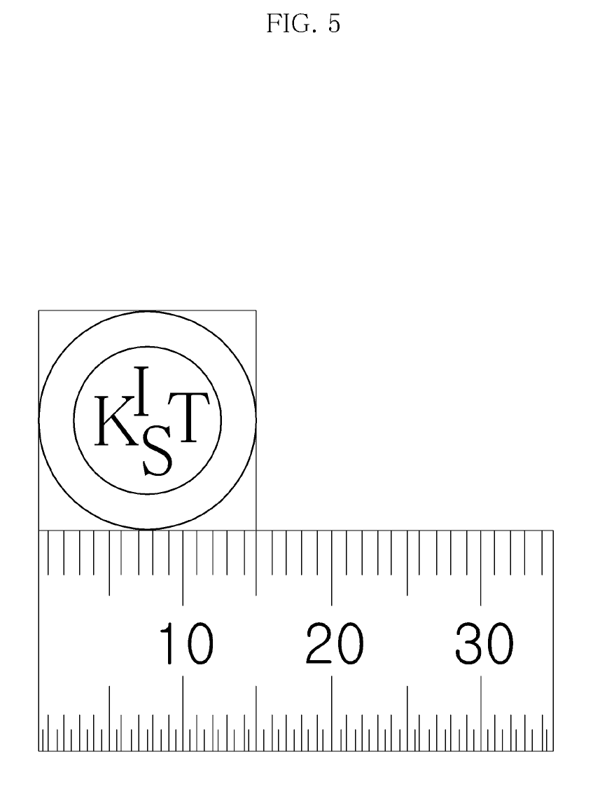

Crystallinity of the graphene nanomeshes was investigated by Raman spectroscopy analysis and the result is shown in FIG. 4. FIG. 5 shows an image of the prepared graphene nanomesh. It can be seen that the nanomesh film is transparent. Accordingly, it is expected that the film can be used for a transparent electronic device.

### Example 2

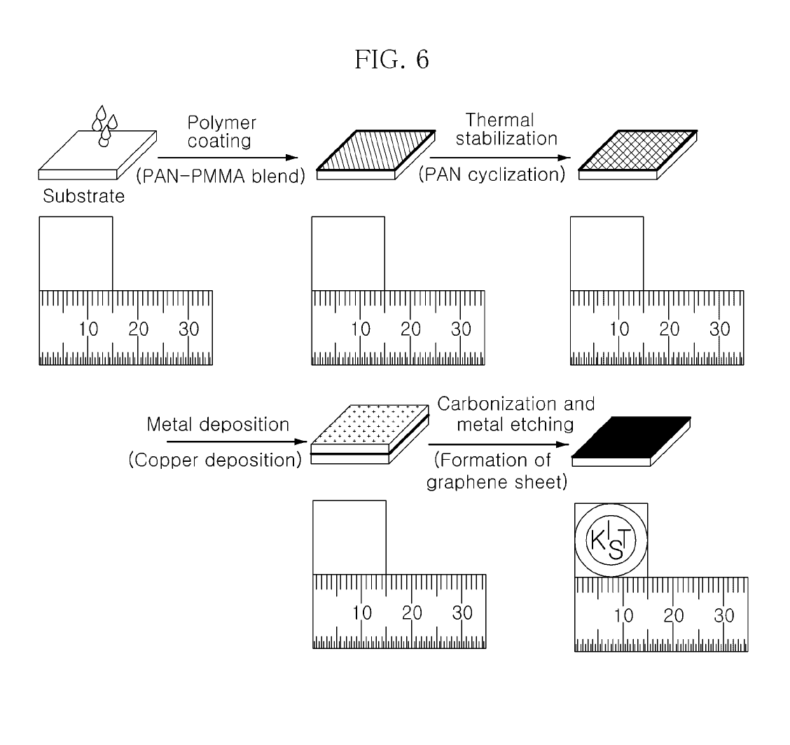

Graphene nanomeshes were prepared in the same procedure as Example 1, except that a 100-nm thick metal (copper) film was deposited on the polymer film to induce formation into a polymer nanomesh and increase crystallinity. FIG. 6 shows the preparation process and images obtained at different steps.

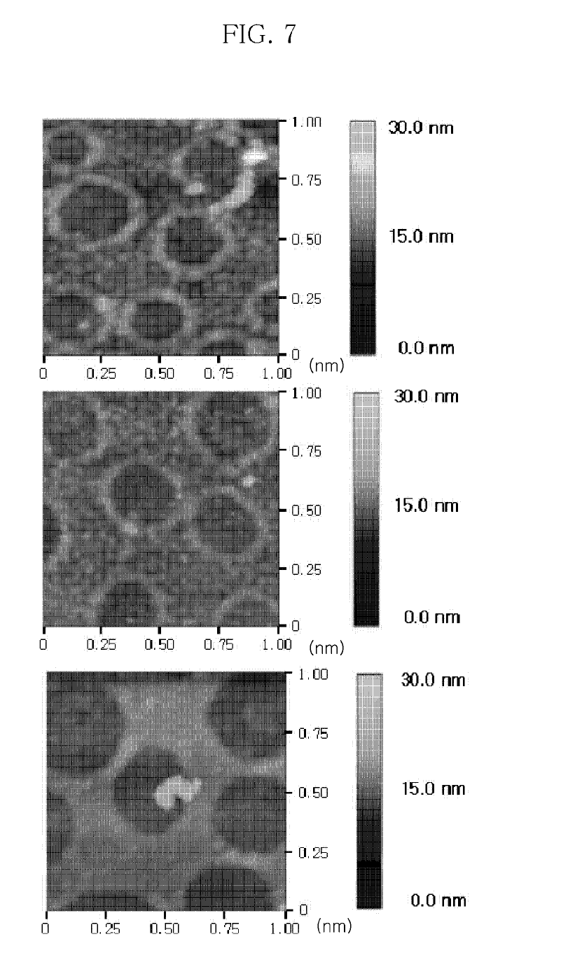

The surface of thus prepared graphene nanomeshes was observed as in Example 1 and the result is shown in FIG. 7.

The graphene nanomeshes on which the metal film was deposited exhibited increased hole size and decreased inter-hole distance for the same mixing ratio. Through the metal film deposition, the inter-hole distance could be reduced to 10 nm or smaller.

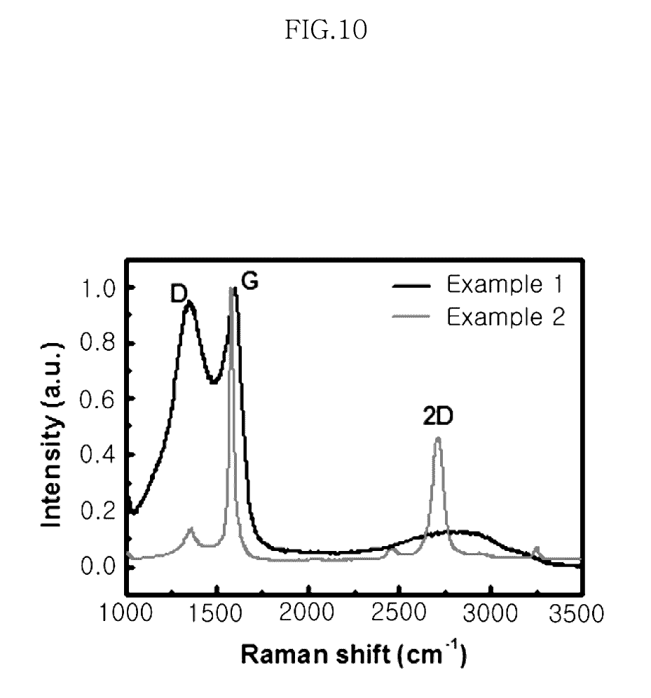

Further, FIG. 10 shows Raman spectra of graphene nanomeshes prepared in Example 1 and Example 2 according to an exemplary embodiment of the present disclosure.

In Raman spectra, three peaks of D (1350 cm⁻¹), G (1580 cm⁻¹) and 2D (2700 cm⁻¹) may be shown. D peak may be an indicator of extent of defects since it is expressed by defects of crystal. G and 2D peaks may be used as indicator of crystallinity. Usually, ratio of D peak intensity to G peak intensity (I_{D}/I_{G}) is used as an indicator of crystallinity and extent of defects. That is, the smaller the ratio (I_{D}/I_{G}), the defects is less and crystallinity is better.

As shown in FIG. 10, while graphene nanomesh of Example 1 (no use of metal film) has a I_{D}/I_{G} ratio of 0.95, graphene nanomesh of Example 2 [metal (copper) film used] has a I_{D}/I_{G} ratio of 0.14. Thus, it can be said that graphene nanomesh made using metal film has less defects and improved crystallinity as compared to graphene nanomesh made without using metal film.

### Example 3

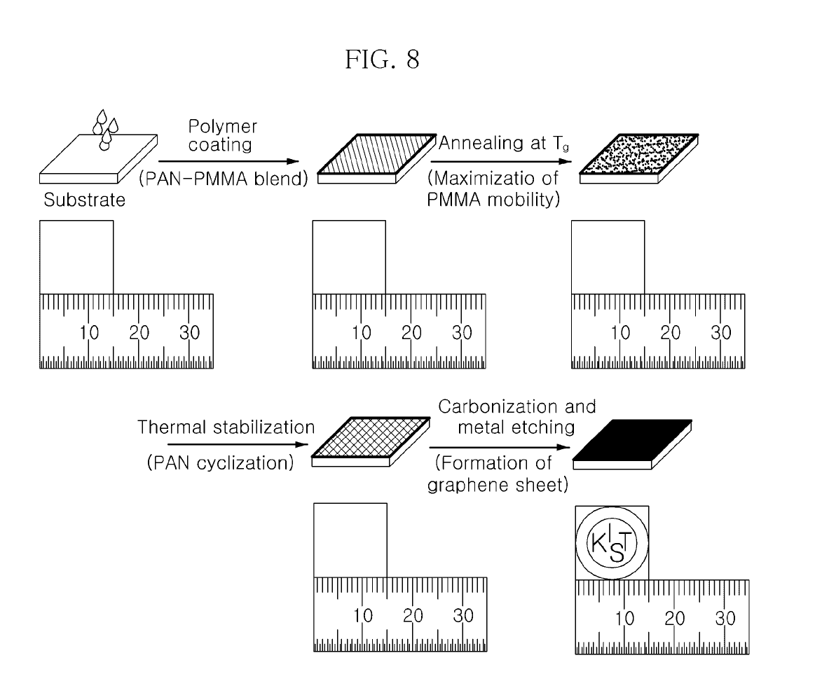

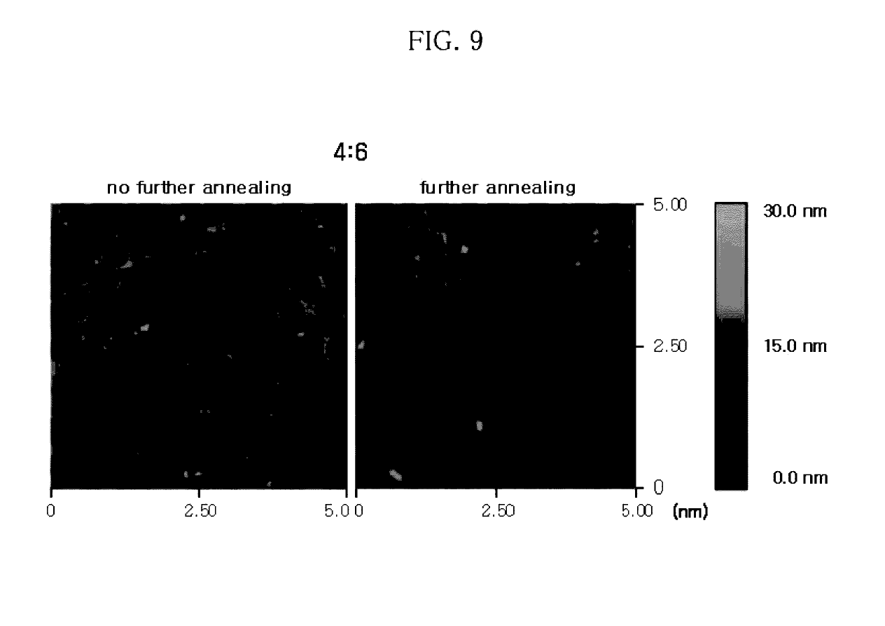

Graphene nanomeshes were prepared in the same procedure as Example 1, except that annealing was further performed at a glass transition temperature of the hole-forming polymer before the thermal stabilization. FIG. 8 shows the preparation process and images obtained at different steps. The annealing was performed at 105° C. for 24 hours under an air atmosphere. The surface of thus prepared graphene nanomeshes was observed as in Example 1 and the result is shown in FIG. 9. It can be seen that the graphene nanomeshes further annealed at the glass transition temperature of the hole-forming polymer has a structure similar to that of the graphene nanomeshes without the annealing.

While the exemplary embodiments have been shown and described, it will be understood by those skilled in the art that various changes in form and details may be made thereto without departing from the spirit and scope of the present disclosure as defined by the appended claims. In addition, many modifications can be made to adapt a particular situation or material to the teachings of the present disclosure without departing from the essential scope thereof. Therefore, it is intended that the present disclosure not be limited to the particular exemplary embodiments disclosed as the best mode contemplated for carrying out the present disclosure, but that the present disclosure will include all embodiments falling within the scope of the appended claims.

What is claimed is:

1. A polymer nanomesh consisting essentially of a planar structure, wherein the planar structure of the polymer nanomesh comprises a cyclized nanomesh-forming polymer and two-dimensional holes arranged on the planer structure.

2. The polymer nanomesh according to claim 1, wherein the nanomesh-forming polymer is cyclized to form the polymer nanomesh, and two-dimensional holes are formed by removal of a hole-forming polymer.

3. The polymer nanomesh according to claim 2, wherein a morphology of the polymer nanomesh depends on a morphology of a phase-separation of the hole-forming polymer and the nanomesh-forming polymer.

4. A carbon nanomesh consisting essentially of a planar structure,
wherein the planar structure of the carbon nanomesh comprises a cyclic structure of carbon atoms and two dimensional holes arranged on the planer structure, and
wherein the cyclic structure of carbon atoms comes from a carbonization of a cyclized nanomesh-forming polymer.

5. The carbon nanomesh according to claim 4,
wherein the two dimensional holes have a hole size of 1 nm˜1 μm.

6. The carbon nanomesh according to claim 4,
wherein the carbon nanomesh has a geometry of inter-hole distance of 1 nm to 1 μm.

7. The carbon nanomesh according to claim 4,
wherein the carbon nanomesh has a thickness of 0.4 nm or more.

8. The carbon nanomesh according to claim 4,
wherein as a size of the holes increase, an inter-hole distance decreases.

9. The carbon nanomesh according to claim 4,
wherein the carbon nanomesh has a band gap of 1 meV˜1 eV.

10. The carbon nanomesh according to claim 4,
wherein a band gap of the carbon nanomesh is controlled by geometry of an inter-hole distance of the carbon nanomesh.

11. The carbon nanomesh according to claim 4,
wherein the carbon nanomesh further comprises a metal film.

12. The carbon nanomesh according to claim 4,
wherein the carbon nanomesh is a graphene nanomesh.

13. A method for preparing a graphene nanomesh, comprising:
preparing a polymer nanofilm by coating a solution of a block copolymer of a pore-forming polymer and a nanomesh-forming polymer or by coating a solution of a polymer mixture of a pore-forming polymer and a nanomesh-forming polymer, on a substrate,
stabilizing the polymer nanofilm such that the pore-forming polymer is removed and the nanomesh-forming polymer is cyclized and forms a stabilized polymer nanomesh with pores; and
carbonizing the stabilized polymer nanomesh with pores to prepare a graphene nanomesh.

14. The method for preparing a graphene nanomesh according to claim 13, which further comprises, before or after said stabilizing, depositing a metal nanofilm on the polymer nanofilm.

15. The method for preparing a graphene nanomesh according to claim 13, which further comprises, in said carbonizing, graphitizing the graphene nanomesh at 1800-3000° C. under an atmosphere of inert gas, hydrogen gas, vacuum or a combination thereof.

16. The method for preparing a graphene nanomesh according to claim 13, wherein said carbonizing is performed in the presence of a doping gas and the doping gas comprises a group 3-7 element.

17. The method for preparing a graphene nanomesh according to claim 13, wherein, in said carbonizing, volatile carbon molecules are injected and the volatile carbon molecules are acetylene, ethylene or methane.
